(19) United States
(12) Patent Application Publication
(10) Pub. No.: US 2009/0134240 A1
(43) Pub. Date: May 28, 2009

(54) Method of making piezoelectrically actuated device

(75) Inventors: Dennis H. Gibson, Chillicothe, IL (US); Alan R. Stockner, Metamora, IL (US); Amy H. Hess, Metamora, IL (US)

Correspondence Address: CATERPILLAR c/o LIELL, MCNEIL & HARPER;Intellectual Property Department, AH9510, 100 N.E. Adams, Peoria, IL, 61629-9510, US

(73) Assignee: Caterpillar Inc.

(21) Appl. No.: 11/986,819

(22) Filed: Nov. 27, 2007

(51) Int. Cl. B05B 1/08; C04B 35/00; B29C 65/00; F02M 51/06; H01L 41/053

(52) U.S. Cl. 239/102.2; 264/104; 264/229; 310/355

(57) ABSTRACT

A method of making a piezoelectrically actuated device includes the steps of compressing a piezoelectric element toward a compression state which is based on a target preload for the piezoelectric element, and elastically deforming a casing for the piezoelectric element toward a spring state which is also based on the target preload for the piezoelectric element. The method further includes plastically deforming the casing about the subassembly when the piezoelectric element and the casing are at their respective compression state and spring state to set a preload of the piezoelectric element at the target preload

### TECHNICAL FIELD

The present disclosure relates generally to piezoelectrically actuated devices, and relates more particularly to making such a device by elastically and plastically deforming different portions of a casing therefor to set an actuator preload at a target preload.

### BACKGROUND

Piezoelectric devices such as actuators have been the subject of much attention in recent years, due to the promises they hold for improved precision, robustness and reliability in various applications. In the art of fuel injectors, piezoelectric actuators are commonly coupled with a control valve to control the timing, duration and rate shape of fuel injection events. In general terms, a piezoelectric actuator will include one or more piezoelectric elements which, when subjected to an electrical potential, experience a conformational change. This phenomenon is leveraged to relatively precisely control the position of a component of interest coupled with the actuator, in the case of a fuel injector a control valve as mentioned above. Despite the heightened interest in piezoelectric actuators, they have yet to achieve widespread commercial use in fuel injectors. Issues relating to manufacturing, assembly and operation of piezoelectric elements used in such actuators continue to challenge fuel system manufacturers.

One problem with piezoelectric actuators relates to setting the “preload” on the piezoelectric element used therein. As is well understood by those familiar with piezoelectric actuators, the piezoelectric element must typically be held in compression for it to respond predictably and reliably to a voltage potential. Many proposals for piezoelectric actuators couple the actuator with a relatively small, low-flow control valve which is moved rapidly to control pressure and/or flow of a larger volume of fuel within a fuel injector. In such instances, the need for predictability and reliability will be readily apparent. Where preload on the piezoelectric element of the actuator is too high or too low, however, the piezoelectric element may not behave as desired. A wide variety of preloading mechanisms and assembly/manufacturing strategies for piezoelectric actuators have been proposed over the years, only relatively few of which have seen success.

One known piezoelectric actuator device is set forth in U.S. Pat. No. 7,145,282 B2 to Oakley et al. (“Oakley”). In several designs proposed by Oakley, preloading of a stack of piezoelectric disks is purportedly achieved via elasticity of a housing for the actuator. This would appear to offer the advantage of not needing a separate spring to apply the preload. The strategy Oakley sets forth for preloading the piezoelectric disks during actuator assembly, however, suffers from certain disadvantages. In particular, Oakley suggests stretching the housing by urging a top seal downward against the stack, then welding the seal to a collar engaging a lip on the housing while the seal compresses the disks. While assembly of the actuator in Oakley may be relatively simple, stretching the housing and preloading the actuator together may make it relatively difficult to achieve a prescribed target preload.

### SUMMARY

In one aspect, a method of making a piezoelectrically actuated device includes the steps of compressing a piezoelectric element toward a compression state which is based on a target preload for the piezoelectric element, and elastically deforming a casing for the piezoelectric element toward a spring state which is also based on the target preload for the piezoelectric element. The method further includes the steps of placing a subassembly which includes the piezoelectric element within the casing, and plastically deforming the casing about the subassembly when the piezoelectric element and the casing are at their respective compression state and spring state to set a preload of the piezoelectric element at the target preload.

In another aspect, an actuator includes a subassembly having a movable element for adjusting a position of a valve, and a piezoelectric element configured to actuate the movable element. The actuator further includes a casing in which the subassembly is at least partially disposed, the casing having an elastic segment with a spring force and an inelastic segment, the casing being coupled with the movable element and holding the subassembly in compression via the spring force to preload the piezoelectric element. The inelastic segment further comprises a plastically deformed segment of the casing trapping the subassembly therein.

In still another aspect, a fuel injector includes an injector body having an injection valve and a control valve assembly for the injection valve disposed therein. The fuel injector further includes an actuator for the control valve assembly which includes a piezoelectric element and a casing, the casing having an elastic segment with a spring force and an inelastic segment coupled with the movable element and holding the subassembly in compression via the spring force to preload the piezoelectric element, wherein the inelastic segment further includes a plastically deformed segment of the casing trapping the piezoelectric element therein.

### BRIEF DESCRIPTION OF THE DRAWINGS

FIG. 1 is a partially sectioned side diagrammatic view of a piezoelectric actuator according to one embodiment;

FIG. 2 is partially sectioned side diagrammatic view of a piezoelectric actuator according to another embodiment;

FIG. 3 is a partially sectioned side diagrammatic view of a fuel injector according to one embodiment;

FIG. 4 is a sectioned diagrammatic view of a piezoelectric actuator at a first stage of an assembly process according to one embodiment; and

FIG. 5 is a sectioned diagrammatic view of a piezoelectric actuator at another stage of an assembly process according to one embodiment.

### DETAILED DESCRIPTION

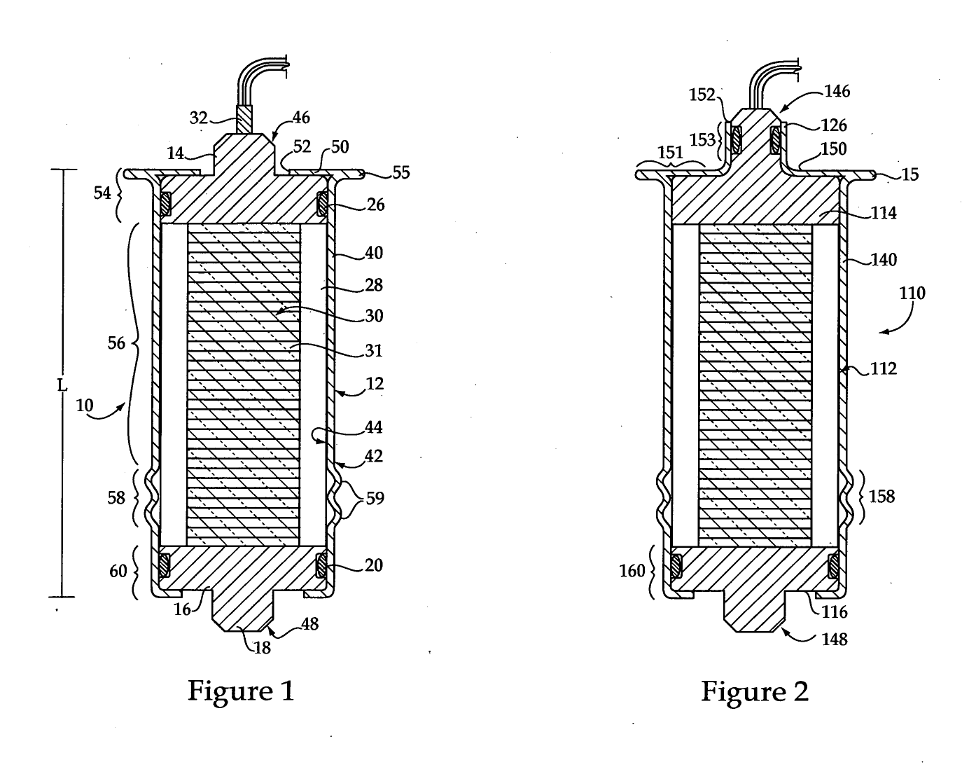

Referring to FIG. 1, there is shown an actuator 10, having a casing 40 with a subassembly 12 disposed at least partially therein. Subassembly 12 may include a piezoelectric element 30, such as a stack of piezoelectric disks 31. A first closure member 14 may be positioned at a first end 46 of actuator 10, whereas a second closure member 16 may be positioned at a second end 48 of actuator 10. An electrical connector 32 may be coupled with closure member 14 and configured to connect with an electrical power source for powering piezoelectric element 30. In one embodiment, closure member 16 may comprise a movable element which is configured to adjust a position of a component of interest by actuating element 30. Closure member 16 may include a contact button 18 located thereon which is configured to contact a valve or the like, as further described herein. A first O-ring 26 or other sealing member may fluidly seal between first closure member 14 and an inner diameter 44 of casing 40, and a second O-ring 20 or other sealing member may fluidly seal between inner diameter 44 of casing 40 and second closure member 16. A thermal layer 28 of material known to those of skill in the relevant art may be positioned around element 30 to assist in thermal management of element 30 during operation, in a conventional manner. As will be further apparent from the following description, the presently disclosed design and method of making actuator 10 is contemplated to provide various advantages over state of the art piezoelectric actuators, particularly with regard to ease of assembly, proper preloading and reliability of operation once in service.

Casing 40 may be generally cylindrical, and may be made at least in part by roll forming steel sheet material, for example. Casing 40 may further have a plurality of segments, including a first segment 54, a second segment 56, a third segment 58 and a fourth segment 60. One or more of these segments may comprise an elastic segment having a spring force. In one embodiment, segment 58 comprises an elastic segment, including at least one corrugation 59 formed in casing 40 and imparting elasticity to casing 40. In the illustrated embodiment, two corrugations 59 are shown, each being circumferential of casing 40, however in other contemplated embodiments fewer than two corrugations, greater than two corrugations, or some other features imparting elasticity to casing 40 such as slots might be used. Moreover, the relative positioning of corrugations 59 might differ in other embodiments. Corrugations 59 might be located adjacent to first segment 54, for example, or spaced from one another. It may be desirable to form corrugations 59 during roll forming casing 40, however, they might be created later in the manufacturing process in certain embodiments. In the embodiment shown, corrugations 59 are exvolute, extending outwardly of outer diameter 42 and having a maximum width greater than a width of adjoining segments of casing 40. In other embodiments, corrugations 59 might be involute, and have a maximum width less than that of adjoining segments of casing 40, or a combination of involute and exvolute corrugations might be used. It is emphasized that elastic segment 58 might include a variety of features or combinations thereof which impart elasticity to casing 40.

Casing 40 may further have one or more inelastic segments, including segments 54, 56 and 60, for example. In one embodiment, segment 60 may comprise a plastically deformed end segment which is coupled with closure member 16 and holds subassembly 12 in compression via the spring force of elastic segment 58. As casing 40 is typically cylindrical, segment 60 may comprise a closed circular perimeter and extend radially inwardly, although alternatives are contemplated wherein inwardly extending tabs or some other feature which does not comprise a closed perimeter is used. Plastically deformed segment 60 can trap subassembly 12 within casing 40 in a state at which the spring force of elastic segment 58 preloads piezoelectric element 30, as further described herein. It may also be noted that closure members 14 and 16, and the other components of subassembly 12 have a uniform width, W, which is approximately equal to or greater than about one-fourth a length L of casing 40. In other embodiments, these relative dimensions might differ, or be non-uniform.

Casing 40 may still further comprise a mounting flange 55 which is located in first segment 54. In one embodiment, segment 54 may comprise another plastically deformed segment which extends radially outwardly to form flange 55. A radially inwardly extending retaining plate or ring 50 may be coupled with flange 55, such as by welding, to trap closure member 14 within casing 40. Retaining plate 50 may further include an aperture 52 which accommodates the portion of closure member 14 whereupon electrical connector 32 is located.

Turning now to FIG. 2, there is shown an alternative embodiment of an actuator 110. Actuator 110 is similar to actuator 10, but has several differences. Actuator 110 includes a casing 140 having a subassembly 112 similar to subassembly 12 of actuator 10 positioned therein. Actuator 110 further includes a first end 146 where a first closure member 114 is located, and a second end 148 where a second closure member 116 is located. Actuator 110 further includes an elastically deformed segment 158, and a plastically deformed segment 160 trapping subassembly 112 in compression within casing 40. A mounting flange 155 similar to that described with regard to actuator 10 is also provided. Actuator 110 differs from actuator 10 primarily with regard to its design at first end 146. A retaining element 150 is coupled with flange 155, but may have a curving profile transitioning between a planar portion 151 and a cylindrical portion 153, which includes an aperture 152. A sealing member such as an O-ring 126 may be positioned between cylindrical portion 153 and closure member 114 to fluidly seal casing 40 at first end 146.

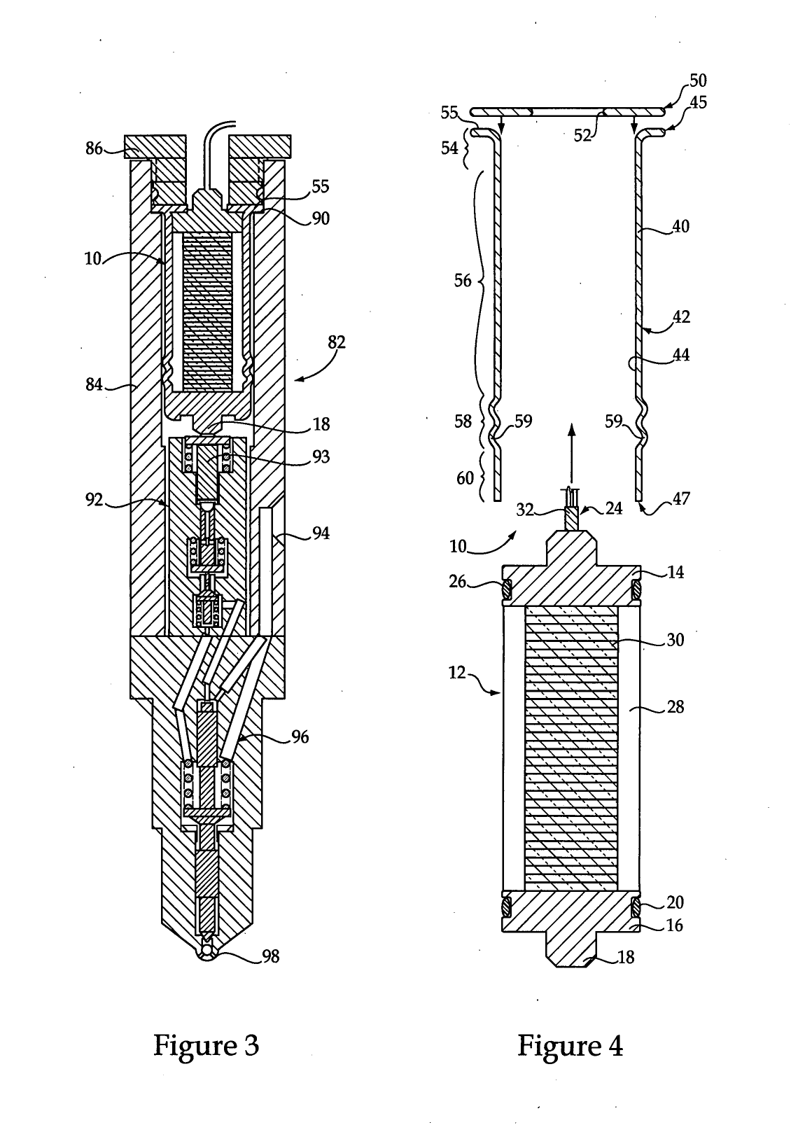

Referring now to FIG. 3, there is shown a fuel injector 82 according to one embodiment, and incorporating a piezoelectric actuator similar to actuator 10 and therefore identified with reference numeral 10. Actuator 110 might also be used in injector 82, as could a variety of other actuators designed and made in accordance with the present disclosure. Injector 82 includes an injector body 84 having an injection valve such as a direct control needle valve 96 disposed therein which is configured to control fuel flow out of one or more nozzle outlets 98. A fluid inlet 94 is located in injector body 84 and configured to connect with a source of pressurized fuel to be supplied to needle valve 96. A control valve assembly 92 which is configured to control needle valve 96 is also positioned within injector body 84. In one embodiment, control valve assembly 92 includes a movable valve member 93 which contacts contact button 18 of actuator 10. Actuator 10 may be actuated to move valve member 93 between first and second positions to control needle valve 96, in a conventional manner. Those skilled in the art will appreciate that other control valve strategies exist with which actuator 10 may be used, and the present disclosure is not limited to the particular injector design shown in FIG. 3, nor even to use in a fuel injector. Injector body 84 further includes a ledge 90 which contacts mounting flange 55, and a load nut 86 which can clamp flange 55 against ledge 90. In one embodiment, load nut 86 may threadedly engage with injector body 84 such that it can be screwed down to secure flange 55, and thereby casing 40 and actuator 10 in place, with contact button 18 positioned in contact with valve member 93. The use of mounting flange 55, in conjunction with the to be described method of making actuator 10, provides a means by which actuator 10 may be secured within injector body 84 without interfering with a preload on piezoelectric element 30.

### INDUSTRIAL APPLICABILITY

Turning to FIG. 4, there is shown actuator 10 at a first assembly stage according to one embodiment. Piezoelectric element 30 is coupled together with closure members 14 and 16 in subassembly 12, O-rings 20 and 26 have been coupled with closure members 16 and 14, respectively, and thermal layer 28 surrounds element 30. Casing 40 has been formed to a cylindrical shape, and corrugations 59 are formed therein. Flange 55 has been formed at a first end 45 of casing 40, for example by plastically deforming segment 54 of casing 40 radially outwardly. Retaining plate 50 is shown as not yet assembled to casing 40. Plastic deformation of casing 40 at a second end 47 has not yet taken place, and thus segment 60 has a cylindrical shape. It should be appreciated that the present disclosure is not limited to assembling the various parts of actuator 10 in a specific order, or performing steps in making actuator 10 in a particular order except where otherwise noted. It should further be appreciated that while the present description focuses on actuator 10, it is similarly applicable to actuator 110 and other actuators contemplated herein.

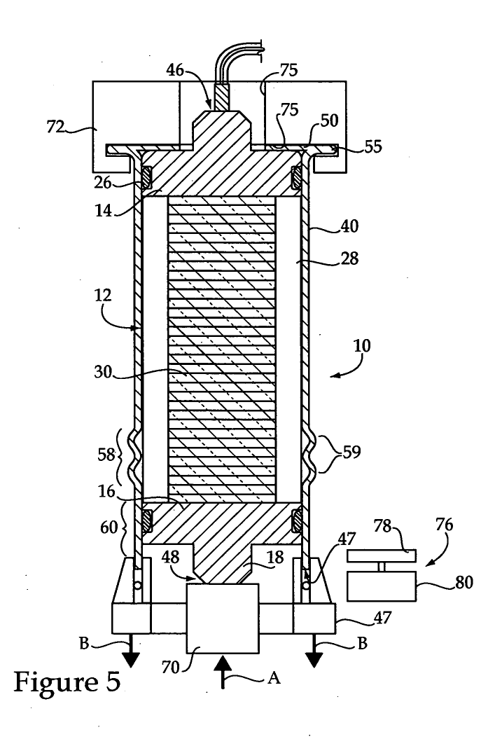

Assembly of actuator 10 from the state shown in FIG. 4 will typically begin by coupling retaining plate 50 with casing 40, and placing subassembly 12 within casing 40 such that closure member 14 extends through aperture 52. This will typically, but not necessarily, entail loading subassembly 12 into casing 40 from end 47 of casing 40. These or similar assembly steps may place actuator 10 in an assembled configuration, ready to have its components secured together and prepared for service. Referring to FIG. 5, there is shown actuator 10 as it might appear after subassembly 12 is placed within casing 40. Actuator 10 is shown supported in a fixture 72. In one embodiment, actuator 10 may be positioned such that flange 55 is clamped by fixture 72 to hold actuator 10 in position, end 46 abuts a bearing surface 73 of fixture 72, and the portion of closure member 14 having electrical connector 32 thereon extends into a recess 75 in fixture 72. It will be readily appreciated by those skilled in the art that alternative fixturing arrangements might be used, and that shown in FIG. 5 is exemplary only.

Once actuator 10 is properly held in a desired orientation, a force producing device 70 may be positioned against contact button 18 and actuated to apply a compressive force to piezoelectric element 30. In one embodiment, force producing device 70 may comprise a linear actuator such as a press, while in other embodiments, a rotational actuator such as threaded components rotatable relative to one another to generate compressive force on element 30, might be used. In any event, piezoelectric element 30 may be compressed toward a compression state which is based on a target preload for piezoelectric element 30. As used herein, the term “target preload” should be understood to refer to a compression state at which piezoelectric element 30 is considered to have a desired behavior upon activation, e.g. extension length or extensive force. It should be appreciated that force producing device 70 need not necessarily compress element 30 to its target preload. Instead, device 70 might compress element 30 to a compression state less than or more than its target preload, as elastic segment 58 will also contribute to the preload state of element 30 once assembly and preparing of actuator 10 is completed. It should thus be appreciated that a compression state for element 30 which is based on its target preload might include a range of compression states. Bearing surface 73 may react the compressive force applied via device 70, which defines a first force vector having a direction illustrated with arrow A in FIG. 5.

Prior to, during or after piezoelectric element 30 has been compressed to the desired compression state, casing 40 may be elastically deformed toward a spring state which is also based on the target preload for piezoelectric element 30. A gripping device 74 may be used to clamp to end 47 of casing 40 and apply a force thereto defining a second force vector having a direction opposed to that of the force vector illustrated with arrow A, and shown with arrows B in FIG. 5. Elastically deforming casing 40 may stretch corrugations 59. When element 30 and casing 40 are at their respective compression state and spring state, a crimping device 76 which may comprise a roller 78 and actuating element 80 may be used to plastically deform segment 60 about closure member 16 to complete assembly and set a preload for element 30 at a target preload. Once assembled, actuator 10 may be placed within injector body 84 such that flange 55 contacts ledge 90, and contact button 18 contacts valve member 93. Load nut 86 may then be secured to injector body 84 to complete assembly. Since ledge 90 serves as a locating surface for actuator 10, and actuator 10 is rigidly clamped within injector body 84 without altering a compressive force on element 30, assembling actuator 10 to injector 82 will not affect the preload on element 30.

As mentioned above, casing 40 may be elastically deformed toward a spring state which is based on the target preload for element 30 prior to placing actuator 10 within injector body 84. Similar to compressing element 30, the subject spring state of casing 40 may lie within a range of spring states. When element 30 is compressed, it may have a tendency to return toward an uncompressed state, whereas when casing 40 is elastically deformed it may have a tendency to return toward a relaxed state. The tendency for casing 40 to relax, and the tendency for element 30 to decompress will result in opposing forces when segment 60 traps subassembly 12 within casing 40. Accordingly, these opposing forces may be balanced to result in element 30 being held at a target preload by varying one or both of the extent to which element 30 is compressed with device 70 and the extent to which casing 40 is elastically deformed with gripping device 74. The presently described method of making actuator 10, 110 or other actuators described herein, thus provides two independent variables which can each be manipulated to preload element 30. This strategy contrasts with many earlier designs, such as Oakley, described above, wherein preloading a piezoelectric element is attempted by way of a single assembly step intended to stretch a housing and compress a piezoelectric element at the same time. By implementing the present disclosure, achieving a target preload is expected to be relatively easier than in such earlier designs.

The present description is for illustrative purposes only, and should not be construed to narrow the breadth of the present disclosure in any way. Thus, those skilled in the art will appreciate that various modifications might be made to the presently disclosed embodiments without departing from the full and fair scope and spirit of the present disclosure. For example, while much of the foregoing description emphasizes actuators in the context of fuel injectors, the present disclosure may find applications outside of fuel systems. Piezoelectric actuators for other purposes such as controlling delivery of relatively minute quantities of fluid in laboratory or manufacturing settings might be designed and constructed according to the teachings set forth herein. Piezoelectric actuators used in vibratory devices might also be made in accordance with the present disclosure. Other aspects, features and advantages will be apparent upon an examination of the attached drawings and appended claims.

What is claimed is:

1. A method of making a piezoelectrically actuated device comprising the steps of:
compressing a piezoelectric element toward a compression state which is based on a target preload for the piezoelectric element;
elastically deforming a casing for the piezoelectric element toward a spring state which is also based on the target preload for the piezoelectric element;
placing a subassembly which includes the piezoelectric element within the casing; and
plastically deforming the casing about the subassembly when the piezoelectric element and the casing are at their respective compression state and spring state to set a preload of the piezoelectric element at the target preload.

2. The method of claim 1 wherein the step of compressing the piezoelectric element comprises compressing the piezoelectric element via a first force vector having a first direction and wherein the step of elastically deforming the casing comprises elastically deforming the casing via a second force vector having a second direction opposed to the first direction.

3. The method of claim 2 wherein the step of plastically deforming the casing about the subassembly comprises trapping the subassembly within the casing at least in part by deforming a segment of the casing having a closed perimeter.

4. The method of claim 3 wherein the step of plastically deforming the casing comprises crimping an end of the casing radially inwardly about the subassembly.

5. The method of claim 2 wherein the placing step comprises placing a subassembly within the casing that includes a closure member for the casing having a contact button located thereon, and wherein the step of compressing the piezoelectric element further comprises contacting the closure member with a force producing device.

6. The method of claim 5 further comprising a step of fluid sealing the subassembly within the casing at least in part with a sealing member.

7. The method of claim 6 wherein the step of fluid sealing the casing comprises positioning an O-ring between the closure member and an inner diameter of the casing.

8. The method of claim 2 wherein the step of elastically deforming the casing further comprises stretching at least one corrugation formed in the casing.

9. The method of claim 1 wherein the casing comprises a first end and a second end, the method further comprises a step of forming a mounting flange at the first end of the casing at least in part by deforming a segment of the casing radially outwardly at the first end, and wherein the placing step further comprises placing the subassembly within the casing from the second end subsequent to the forming step and prior to the plastically deforming step.

10. The method of claim 9 wherein the device comprises a fuel injector and the method further comprises a step of mounting the casing within a fuel injector body without interfering with the preload on the piezoelectric element at least in part by positioning the mounting flange in contact with a ledge located within the fuel injector housing.

11. An actuator comprising:
a subassembly which includes a movable element for adjusting a position of a valve, and a piezoelectric element configured to actuate said movable element; and
a casing in which said subassembly is at least partially disposed, said casing having an elastic segment with a spring force and an inelastic segment, said casing being coupled with said movable element and holding said subassembly in compression via said spring force to preload said piezoelectric element, wherein said inelastic segment further comprises a plastically deformed segment of said casing trapping said subassembly therein.

12. The actuator of claim 11 wherein said elastic segment comprises at least one corrugation and wherein said inelastic segment comprises an end segment of said casing having a closed perimeter and extending radially inwardly.

13. The actuator of claim 12 wherein said movable element comprises a closure member for said casing which includes a contact button.

14. The actuator of claim 13 wherein said casing has an inner diameter, and further comprising a sealing member positioned between said closure member and said inner diameter to fluid seal said casing.

15. The actuator of claim 14 wherein said casing has a first end and a second end, said closure member being located at said second end, and said actuator further comprising another plastically deformed segment located at said first end and including a mounting flange, another closure member comprising electrical connectors located at said first end and another sealing member fluid sealing said casing at said second end and positioned between said inner diameter and said another closure member.

16. A fuel injector comprising:
an injector body having an injection valve and a control valve assembly for said injection valve disposed therein; and
an actuator for said control valve assembly which comprises a piezoelectric element and a casing, said casing having an elastic segment with a spring force and an inelastic segment coupled with said movable element and holding said subassembly in compression via said spring force to preload said piezoelectric element, wherein said inelastic segment further comprises a plastically deformed segment of said casing trapping said piezoelectric element therein.

17. The fuel injector of claim 16 wherein said casing further comprises a mounting flange configured to mount said actuator within said injector body without interfering with a preload on said piezoelectric element, said mounting flange being located at one end of said casing and said plastically deformed segment being located at an opposite end of said casing.

18. The fuel injector of claim 17 wherein said elastic segment comprises at least one corrugation.

19. The fuel injector of claim 17 wherein said casing comprises an inner diameter, wherein said actuator further comprises a first closure member located at a first end of said casing and a first sealing member located between said first closure member and said inner diameter, and a second closure member having a contact button thereon and located at a second end of said casing and a second sealing member located between said second closure member and said inner diameter.

20. The fuel injector of claim 19 wherein said casing comprises an inwardly extending retaining plate coupled with said mounting flange and trapping said second closure member within said casing at said second end.
